(19) United States
(12) Patent Application Publication
(10) Pub. No.: US 2023/0037563 A1
(43) Pub. Date: Feb. 9, 2023

(54) METAL CONTAINING PHOTORESIST DEVELOPER COMPOSITION, AND METHOD OF FORMING PATTERNS INCLUDING DEVELOPING STEP USING THE SAME

(71) Applicants: SAMSUNG SDI CO., LTD., Yongin-si (KR); SAMSUNG ELECTRONICS CO., LTD., Suwon-si (KR)

(72) Inventors: Ryunmin HEO, Suwon-si (KR); Hyungrang MOON, Suwon-si (KR); Minyoung LEE, Suwon-si (KR); Minsoo KIM, Suwon-si (KR); Youngkwon KIM, Suwon-si (KR); Jaehyun KIM, Suwon-si (KR); Changsoo WOO, Suwon-si (KR); Jung Min CHOI, Suwon-si (KR); Moohyun KOH, Hwaseong-si (KR); Jungah KIM, Hwaseong-si (KR); Sungan DO, Hwaseong-si (KR); Sang Won BAE, Suwon-si (KR); Hoon HAN, Hwaseong-si (KR); SukKoo HONG, Hwaseong-si (KR)

(21) Appl. No.: 17/858,924

(22) Filed: Jul. 6, 2022

(30) Foreign Application Priority Data
Jul. 8, 2021 (KR) 10-2021-0089813
May 18, 2022 (KR) 10-2022-0061046

(51) Int. Cl. G03F 7/32

(52) U.S. Cl. CPC G03F 7/325

(57) ABSTRACT

A metal-containing photoresist developer composition, and a method of forming patterns including a step of developing using the same are provided. The metal-containing photoresist developer composition includes an organic solvent, and a heptagonal ring compound substituted with at least one hydroxy group (—OH). The heptagonal ring compound has at least two double bonds in the ring.

### CROSS-REFERENCE TO RELATED APPLICATIONS

This application claims priority to and the benefit of Korean Patent Application No. 10-2021-0089813, filed in the Korean Intellectual Property Office on Jul. 8, 2021, and Korean Patent Application No. 10-2022-0061046, filed in the Korean Intellectual Property Office on May 18, 2022, the entire contents of both applications are hereby incorporated by reference.

### BACKGROUND

### 1. Field

Aspects of one or more embodiments of the present disclosure relate to a metal-containing photoresist developer composition and a method of forming patterns including a developing step (e.g., act or task) utilizing the same.

### 2. Description of the Related Art

In recent years, a semiconductor industry has been accompanied by a substantially continuous reduction of critical dimensions, and this dimensional reduction requires new types (kinds) of high-performance photoresist materials and a patterning method that satisfy a demand for processing and patterning with increasingly smaller features (dimensions).

Related art chemically amplified (CA) photoresists are designed to secure high sensitivity, but because a typical elemental makeup thereof (primarily, C including smaller quantities of O, F, and/or S) lowers absorbance at a wavelength of about 13.5 nm and as a result, thereby reduces sensitivity, and the photoresists may thus suffer more difficulties partially under the EUV (Extreme UltraViolet) exposure. In some embodiments, the CA photoresists may have difficulties due to roughness issues that result from small feature sizes, and are due partially to the nature of the acid catalyst processes. It has been experimentally determined that LER (line edge roughness) increases as a photospeed decreases. Due to these drawbacks and problems of the CA photoresist a new type or kind of high-performance photoresists is both desired and required in the semiconductor industry.

For example, it is desired to develop a photoresist capable of securing excellent or suitable etching resistance and resolution and concurrently (e.g., simultaneously), improving sensitivity and enhancing CD (critical dimension) uniformity and having suitable or improve LER (line edge roughness) characteristics in the photolithography process.

### SUMMARY

An aspect of one or more embodiments of the present disclosure is directed toward a metal-containing photoresist developer composition.

Another aspect of one or more embodiments of the present disclosure is directed toward a method of forming patterns including a step (e.g., act or task) of developing utilizing the foregoing composition.

Additional aspects will be set forth in part in the description which follows and, in part, will be apparent from the description, or may be learned by practice of the presented embodiments of the disclosure.

A metal-containing photoresist developer composition according to an embodiment includes an organic solvent, and a heptagonal ring compound substituted with at least one hydroxyl group (—OH), wherein the heptagonal ring compound has at least two double bonds in the ring.

The heptagonal ring compound may be substituted with one or two hydroxyl groups (—OH).

The heptagonal ring compound may have three double bonds.

The heptagonal ring compound may be represented by Chemical Formula 1.

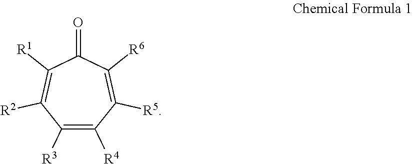

In Chemical Formula 1,

R¹ to R⁶ may each independently be hydrogen, a halogen, a hydroxy group, an amino group, a substituted or unsubstituted C1 to C30 amine group, a substituted or unsubstituted C1 to C10 alkyl group, or a substituted or unsubstituted C6 to C20 aryl group, and

at least one of R¹ to R⁶ may be a hydroxy group.

The heptagonal ring compound may be selected from the formulas of Group 1.

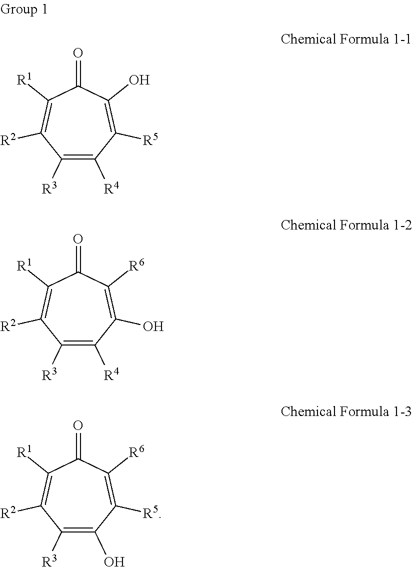

In Group 1,

R¹ to R⁶ may each independently be hydrogen, a halogen, an amino group, a substituted or unsubstituted C1 to C30 amine group, a substituted or unsubstituted C1 to C10 alkyl group, or a substituted or unsubstituted C6 to C20 aryl group.

The heptagonal ring compound may be 2-hydroxy-2,4,6-cycloheptatrien-1-one.

The metal-containing photoresist developer composition may include about 50 wt % to about 99.99 wt % of the organic solvent; and about 0.01 wt % to about 50 wt % of the heptagonal ring compound.

The metal-containing photoresist may include at least one metal compound selected from among an alkyl tin oxo group and an alkyl tin carboxyl group.

The metal-containing photoresist may include a metal compound represented by Chemical Formula 3.

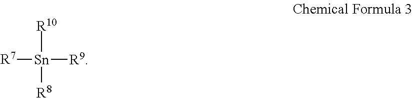

In Chemical Formula 3,

R⁷ may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C6 or C30 arylalkyl group, or —R^{a}—O—R_{b} (wherein R^{a} is a substituted or unsubstituted C1 to C20 alkylene group and R^{b} is a substituted or unsubstituted C1 to C20 alkyl group),

R⁸ to R¹⁰ may each independently be —OR^{c} or —OC(═O)R^{d},

R^{c} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and

R^{d} may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof.

A method of forming patterns according to an embodiment includes coating a metal-containing photoresist composition on a substrate, coating the composition for removing edge beads from the metal-containing photoresist along the edge of the substrate, drying and heating the resultant (i.e., the substrate after the coating steps or acts) to form a metal-containing photoresist film on the substrate, exposing the metal-containing photoresist film, and developing the same utilizing the aforementioned metal-containing photoresist developer composition.

The metal-containing photoresist developer composition according to an embodiment minimizes or reduces defects present in the metal-containing photoresist film after the exposure process and enables easy (or improved) development, thereby realizing excellent or suitable contrast characteristics.

### BRIEF DESCRIPTION OF THE DRAWINGS

The accompanying drawings are included to provide a further understanding of the present disclosure, and are incorporated in and constitute a part of this disclosure. The drawings illustrate example embodiments of the present disclosure and, together with the description, serve to explain principles of the present disclosure. In the drawings:

FIG. 1 is a cross-sectional view illustrating a process sequence in order to explain a method of forming patterns.

FIG. 2 is a cross-sectional view illustrating a process sequence in order to explain a method of forming patterns.

FIG. 3 is a cross-sectional view illustrating a process sequence in order to explain a method of forming patterns.

### DETAILED DESCRIPTION

Hereinafter, embodiments of the present disclosure will be described in more detail with reference to the accompanying drawings. In the following description of the present disclosure, generally used/generally available functions or constructions may not be provided. The present disclosure may be embodied in different forms and should not be construed as limited to the embodiments set forth herein. Rather, all modifications, equivalents, and substituents which are included in the spirit and technical scope of the present disclosure should be included in the present disclosure.

In order to clearly and succinctly illustrate the present disclosure, some description and relationships may be omitted, and throughout the disclosure, the same or similar configuration elements are designated by the same reference numerals. Also, because the size and thickness of each configuration shown in the drawing may be arbitrarily shown for better understanding and ease of description, the present disclosure is not necessarily limited thereto.

In the drawings, the thickness of layers, films, panels, regions, etc., may be exaggerated for clarity. In the drawings, the thickness of a part of layers or regions, etc., may be exaggerated for clarity. It will be understood that when an element such as a layer, film, region, or substrate is referred to as being “on” another element, it can be directly on the other element or intervening elements may also be present.

In the present disclosure, “substituted” refers to replacement of a hydrogen atom by deuterium, a halogen group, a hydroxyl group, an amino group, a substituted or unsubstituted C1 to C30 amine group, a nitro group, a substituted or unsubstituted C1 to C40 silyl group, a C1 to C30 alkyl group, a C1 to C10 haloalkyl group, a C1 to C10 alkylsilyl group, a C3 to C30 cycloalkyl group, a C6 to C30 aryl group, a C1 to C20 alkoxy group, or a cyano group. “Unsubstituted” refers to a hydrogen atom that remains as a hydrogen atom without being replaced by another substituent.

In the present disclosure, unless otherwise defined, the term “heptagonal ring compound” refers to a compound having a structure in which the terminal atoms constituting a molecule are linked to each other to form a heptagonal ring, and according to the type or kind of atoms forming the ring, it may be classified as a ‘carbocyclic compound’ and a ‘heterocyclic compound’.

The ‘carbocyclic compound’ refers to a compound in which a ring-forming atom is only carbon.

The ‘heterocyclic compound’ refers to a compound including a hetero atom in addition to carbon atoms forming a ring.

The hetero atom that may be contained in the ‘heterocyclic compound’ may include, but is not limited to, N, O, S, P, Si, and/or the like.

In the present disclosure, the term “alkyl group” refers to a linear or branched aliphatic hydrocarbon group, unless otherwise defined. The alkyl group may be a “saturated alkyl group” that does not contain any double or triple bonds.

The alkyl group may be a C1 to C20 alkyl group. For example, the alkyl group may be a C1 to C10 alkyl group or a C1 to C6 alkyl group. For example, a C1 to C4 alkyl group refers to an alkyl chain that contains 1 to 4 carbon atoms, and may be selected from among methyl, ethyl, propyl, iso-propyl, n-butyl, iso-butyl, sec-butyl, and t-butyl groups.

Specific examples of the alkyl group include a methyl group, an ethyl group, a propyl group, an isopropyl group, a butyl group, an isobutyl group, a t-butyl group, a pentyl group, a hexyl group, a cyclopropyl group, a cyclobutyl group, a cyclopentyl group, a cyclohexyl group, etc.

In the present disclosure, the term “cycloalkyl group” refers to a monovalent cyclic aliphatic hydrocarbon group unless otherwise defined.

In the present disclosure, the term “alkenyl group”, unless otherwise defined, is a linear or branched aliphatic hydrocarbon group, and refers to an aliphatic unsaturated alkenyl group containing one or more double bonds.

In the present disclosure, the term “alkynyl group”, unless otherwise defined, is a linear or branched aliphatic hydrocarbon group, and refers to an unsaturated alkynyl group containing one or more triple bonds.

In the present disclosure, “aryl group” refers to a substituent in which all elements of a cyclic substituent have p-orbitals, and these p-orbitals form a conjugate. It may include monocyclic or fused ring polycyclic (i.e., rings that share adjacent pairs of carbon atoms) functional groups.

Hereinafter, a metal-containing photoresist developer composition according to an embodiment is described in more detail.

A metal-containing photoresist developer composition according to an embodiment of the present disclosure includes an organic solvent and a heptagonal ring compound substituted with at least one hydroxyl group (—OH), wherein the heptagonal ring compound has at least two double bonds in the ring.

The “double bond” is included in at least two in the ring, and a form in which the double bond is continuously included is excluded due to the nature of the rigid structure of the heptagonal ring compound. The ‘having at least two double bonds in the ring’ refers to two double bonds that are included via at least one single bond.

The metal-containing photoresist developer composition includes the heptagonal ring compound substituted with the hydroxyl group (—OH), and the hydroxyl group (—OH) is coordinated with the metal-containing resist, and thus by applying the composition including the same, defects present in the metal-containing photoresist film after the exposure process may be minimized or reduced and developed easily (or easier than a composition that does not include the heptagonal ring compound), thereby realizing excellent or suitable contrast characteristics.

For example, the heptagonal ring compound may be substituted with one or two hydroxyl groups (—OH).

The heptagonal ring compound may have three double bonds.

For example, the heptagonal ring compound may be represented by Chemical Formula 1.

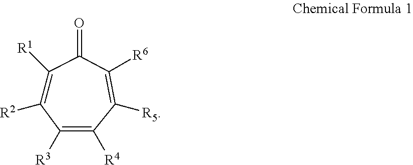

In Chemical Formula 1,

R¹ to R⁶ may each independently be hydrogen, a halogen, a hydroxy group, an amino group, a substituted or unsubstituted C1 to C30 amine group, a substituted or unsubstituted C1 to C10 alkyl group, or a substituted or unsubstituted C6 to C20 aryl group, and

at least one of R¹ to R⁶ may be a hydroxy group.

As a specific example, the heptagonal ring compound may be selected from the chemical formulas of Group 1.

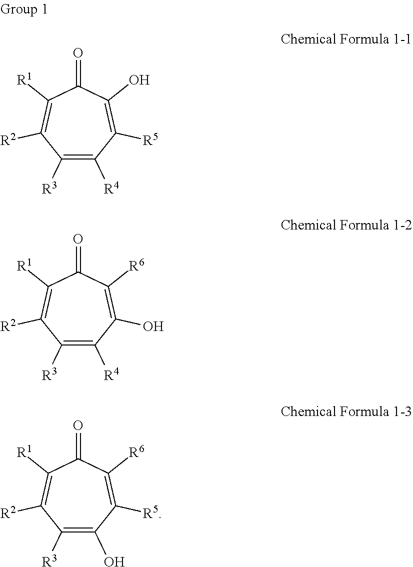

In Group 1,

R¹ to R⁶ may each independently be hydrogen, a halogen, an amino group, a substituted or unsubstituted C1 to C30 amine group, a substituted or unsubstituted C1 to C10 alkyl group, or a substituted or unsubstituted C6 to C20 aryl group.

For example, the heptagonal ring compound may be 2-hydroxy-2,4,6-cycloheptatrien-1-one, or tropolone.

In an embodiment, the metal-containing photoresist developer composition includes about 50 wt % to about 99.99 wt % of the organic solvent and about 0.01 wt % to about 50 wt % of the aforementioned heptagonal ring compound.

In an embodiment, the metal-containing photoresist developer composition may include the aforementioned heptagonal ring compound in an amount of about 0.01 wt % to about 30 wt %, about 0.01 wt % to about 20 wt %, or about 0.05 wt % to about 10 wt %.

Examples of the organic solvent included in the metal-containing photoresist developer composition according to the embodiment may include at least one selected from among ether, alcohol, glycol ether, aromatic hydrocarbon compounds, ketone, and ester, but are not limited thereto. For example, the organic solvent may include ethyleneglycolmonomethylether, ethyleneglycolmonoethylether, methylcellosolveacetate, ethylcellosolveacetate, diethyleneglycolmethylether, diethyleneglycolethylether, propyleneglycol, propyleneglycolmethylether (PGME), propyleneglycolmethyletheracetate (PGMEA), propyleneglycolethylether, propyleneglycolethyletheracetate, propyleneglycolpropyletheracetate, propyleneglycolbutylether, propyleneglycolbutyletheracetate, ethanol, propanol, isopropylalcohol, isobutylalcohol, 4-methyl-2-pentenol (or referred to as methyl isobutyl carbinol (MIBC)), hexanol, 1-methoxy-2-propanol, 1-ethoxy-2-propanol, ethyleneglycol, propyleneglycol, heptanone, propylenecarbonate, butylene carbonate, toluene, xylene, methylethylketone, cyclopentanone, cyclohexanone, 2-hydroxy ethyl propionate, 2-hydroxy-2-methyl ethyl propionate, ethoxy ethyl acetate, hydroxy ethyl acetate, 2-hydroxy-3-methylmethyl butanoate, 3-methoxy methyl propionate, 3-methoxy ethyl propionate, 3-ethoxy ethyl propionate, 3-ethoxy methyl propionate, methyl pyruvate, ethyl pyruvate, ethyl acetate, butyl acetate, ethyl lactate, butyl lactate, gamma-butyrolactone, methyl-2-hydroxyisobutyrate, methoxybenzene, n-butyl acetate, 1-methoxy-2-propyl acetate, methoxyethoxy propinonate, ethoxyethoxy propinonate, or one or more combinations thereof, but is not limited thereto.

When the additives described below are included, the organic solvent may be included in a balance amount except for the included components.

The metal-containing photoresist developer composition according to the present disclosure may further include at least one selected from among a surfactant, a dispersant, a moisture absorbent, and a coupling agent.

The surfactant may serve to improve coating uniformity and improve wetting of the photoresist composition. In example embodiments, the surfactant may be a sulfuric acid ester salt, a sulfonic acid salt, a phosphoric acid ester, a soap, an amine salt, a quaternary ammonium salt, a polyethylene glycol, an alkylphenol ethylene oxide adduct, a polyhydric alcohol, a nitrogen-containing vinyl polymer, or one or more combinations thereof, but is not limited thereto. For example, the surfactant may include an alkylbenzenesulfonate salt, an alkylpyridinium salt, polyethylene glycol, or a quaternary ammonium salt. When the photoresist composition includes the surfactant, the surfactant may be included in an amount of about 0.001 wt % to about 3 wt % based on the total weight of the photoresist composition.

The dispersant may serve to substantially uniformly disperse each component constituting the photoresist composition in the photoresist composition. In an embodiment, the dispersant may be an epoxy resin, polyvinyl alcohol, polyvinyl butyral, polyvinylpyrrolidone, glucose, sodium dodecyl sulfate, sodium citrate, oleic acid, linoleic acid, or one or more combinations thereof but is not limited thereto. When the photoresist composition includes the dispersant, the dispersant may be included in an amount of about 0.001 wt % to about 5 wt % based on the total weight of the photoresist composition.

The moisture absorbent may serve to prevent or reduce adverse effects by moisture in the photoresist composition. For example, the moisture absorbent may serve to prevent or reduce the metal included in the photoresist composition from being oxidized by moisture. In an embodiment, the moisture absorbent may be polyoxyethylene nonylphenolether, polyethylene glycol, polypropylene glycol, polyacrylamide, or one or more combinations thereof, but is not limited thereto. When the photoresist composition includes the moisture absorbent, the moisture absorbent may be included in an amount of about 0.001 wt % to about 10 wt % based on the total weight of the photoresist composition.

The coupling agent may serve to improve adhesion to the lower film when the photoresist composition is coated on the lower film. In an embodiment, the coupling agent may include a silane coupling agent. The silane coupling agent may be vinyltrimethoxysilane, vinyltriethoxysilane, vinyl trichlorosilane, vinyltris(β-methoxyethoxy)silane, 3-methacryloxypropyltrimethoxysilane, 3-acryloxypropyl trimethoxysilane, p-styryl trimethoxysilane, 3-methacryloxypropylmethyldimethoxysilane, 3-methacryloxypropylmethyldiethoxysilane, or trimethoxy[3-(phenylamino)propyl]silane, but is not limited thereto. When the photoresist composition includes the coupling agent, the coupling agent may be included in an amount of about 0.001 wt % to about 5 wt % based on the total weight of the photoresist composition.

The metal-containing photoresist may include at least one metal compound selected from among an alkyl tin oxo group and an alkyl tin carboxyl group.

For example, the metal-containing photoresist may include a metal compound represented by Chemical Formula 3.

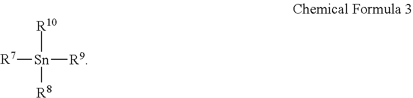

In Chemical Formula 3,

R⁷ may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C6 or C30 arylalkyl group, or —R^{a}—O—R^{b} (wherein R^{a} is a substituted or unsubstituted C1 to C20 alkylene group and R^{b} is a substituted or unsubstituted C1 to C20 alkyl group),

R⁸ to R¹⁰ may each independently be —OR^{c} or —OC(═O)R^{d},

R^{c} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or one or more combinations thereof, and

R^{d} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or one or more combinations thereof.

In some embodiments, a method of forming patterns includes the step (e.g., act or task) of development utilizing the aforementioned metal-containing photoresist developer composition. For example, the manufactured pattern may be a negative-type or kind photoresist pattern.

A method of forming patterns according to an embodiment includes coating a metal-containing photoresist composition on a substrate, coating the composition for removing edge beads from the metal-containing photoresist along the edge of the substrate, drying and heating the resultant (i.e., the substrate after the coating steps or acts) to form a metal-containing photoresist film on the substrate, exposing the metal-containing photoresist film, and developing the same utilizing the aforementioned metal-containing photoresist developer composition.

For example, the forming of patterns utilizing the metal-containing photoresist composition may include coating a metal-containing photoresist composition on a substrate on which a thin film is formed by spin coating, slit coating, inkjet printing, etc., and drying the coated metal-containing photoresist composition to form a photoresist film. The metal-containing photoresist composition may include a tin-based compound, and for example, the tin-based compound may include at least one selected from among an alkyl tin oxo group, an alkyl tin carboxyl group, and an alkyl tin hydroxy group.

Subsequently, the composition for removing edge beads from the metal-containing photoresist may be coated along the edge of the substrate.

Next, a first heat treatment process of heating the substrate on which the metal-containing photoresist film is formed is performed. The first heat treatment process may be performed at a temperature of about 80° C. to about 120° C. In this process, the solvent is evaporated and the metal-containing photoresist film may be more firmly adhered to the substrate.

And the photoresist film is selectively exposed.

For example, examples of light that may be utilized in the exposure process may include not only light having a short wavelength such as i-line (wavelength 365 nm), KrF excimer laser (wavelength of 248 nm), and/or ArF excimer laser (wavelength of 193 nm), but also EUV (light having a high energy wavelength such as EUV (Extreme UltraViolet, wavelength of 13.5 nm), E-Beam (electron beam), etc.

For example, the light for exposure according to an embodiment may be short-wavelength light having a wavelength range of about 5 nm to about 150 nm, and light having a high energy wavelength such as EUV (Extreme UltraViolet, wavelength 13.5 nm), E-Beam (electron beam), etc.

In the step (e.g., act or task) of forming the photoresist pattern, a negative-type or kind pattern may be formed.

The exposed region of the photoresist film has a solubility different from that of the unexposed region of the photoresist film as a polymer is formed by a crosslinking reaction such as condensation between organometallic compounds.

Then, a second heat treatment process is performed on the substrate. The second heat treatment process may be performed at a temperature of about 90° C. to about 200° C. By performing the second heat treatment process, the exposed region of the photoresist film becomes difficult to be dissolved in a developer solution.

For example, the photoresist pattern corresponding to the negative-type or kind tone image may be completed by dissolving and then removing the photoresist film corresponding to the unexposed region utilizing the aforementioned photoresist developer.

As described above, the photoresist pattern formed by exposure to not only light having a wavelength such as i-line (wavelength of 365 nm), KrF excimer laser (wavelength of 248 nm), and/or ArF excimer laser (wavelength of 193 nm), but also EUV (Extreme UltraViolet; wavelength of 13.5 nm), and/or light having high energy such as an E-beam (electron beam) may have a thickness width of about 5 nm to about 100 nm. For example, the photoresist pattern may be formed to have a thickness width of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, or about 5 nm to about 20 nm.

In contrast, the photoresist pattern may have a pitch having a half-pitch of less than or equal to about 50 nm, for example less than or equal to about 40 nm, for example less than or equal to about 30 nm, for example less than or equal to about 20 nm, for example less than or equal to about 15 nm, and a line width roughness of less than or equal to about 10 nm, less than or equal to about 5 nm, less than or equal to about 3 nm, or less than or equal to about 2 nm.

Hereinafter, a method of forming patterns is described in more detail with reference to the drawings.

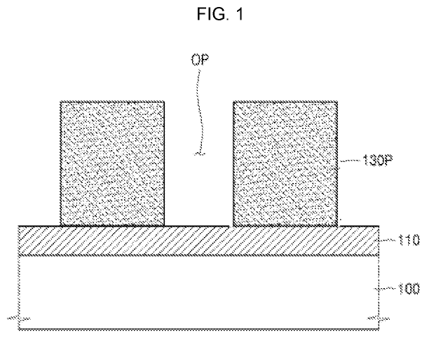

FIGS. 1 to 3 are cross-sectional views illustrating a process sequence in order to further explain a method of forming patterns.

Referring to FIG. 1, the exposed photoresist film is developed to form a photoresist pattern 130P.

In an example embodiment, the exposed photoresist film may be developed to remove an unexposed region of the photoresist film, and the photoresist pattern 130P including the exposed region of the photoresist film may be formed. The photoresist pattern 130P may include a plurality of openings OP.

In an example embodiment, the development of the photoresist film may be performed through an NTD (negative-tone development) process. Herein, the metal-containing photoresist developer composition according to an embodiment may be utilized as a developer composition.

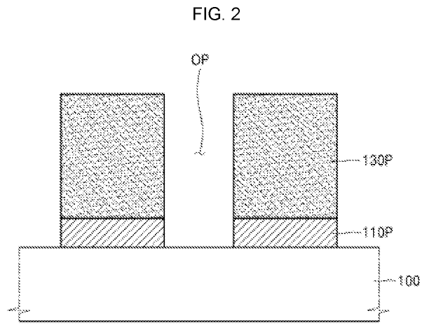

Referring to FIG. 2, the photoresist pattern 130P is utilized to process a feature layer 110 in the result of FIG. 1.

For example, the feature layer 110 is processed through one or more suitable processes of etching a feature layer 110 exposed through the openings OP of the photoresist pattern 130P, injecting impurity ions into the feature layer 110, forming an additional film on the feature layer 110 through the openings OP, deforming (e.g., developing) a portion of the feature layer 110 through the openings OP, and/or the like. FIG. 2 illustrates an example of the process of processing (e.g., developing) a feature pattern 110P by etching the feature layer 110 exposed through the openings OP.

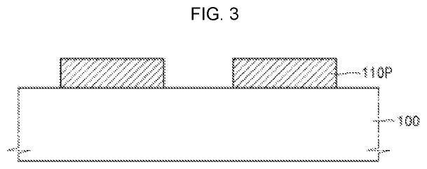

Referring to FIG. 3, the photoresist pattern 130P remaining on the feature pattern 110P is removed in the result of (i.e., the pattern after the removal of the remaining photoresist pattern 130P) FIG. 2. In order to remove the photoresist pattern 130P, an ashing and stripping process may be utilized.

Hereinafter, the present disclosure will be described in more detail through examples relating to the preparation of the aforementioned metal-containing photoresist developer composition. However, the technical features of the present disclosure are not limited by the following examples.

### Preparation of Metal-containing Photoresist Developer Composition

### Example 1

0.05 wt % of 2-hydroxy-2,4,6-cycloheptatriene-1-one (tropolone) and 99.95 wt % of propylene glycol monomethyl ether acetate (PGMEA) were added to a polypropylene (PP) bottle and stirred for 24 hours to prepare a developer composition.

### Example 2

A developer composition was prepared in substantially the same manner as in Preparation Example 1, except that 0.1 wt % of 2-hydroxy-2,4,6-cycloheptatriene-1-one was utilized.

### Example 3

A developer composition was prepared in substantially the same manner as in Preparation Example 1, except that 5.0 wt % of 2-hydroxy-2,4,6-cycloheptatriene-1-one was utilized.

### Comparative Example 1

A developer composition was prepared in substantially the same manner as in Preparation Example 1, except that 2-hydroxy-2,4,6-cycloheptatriene-1-one was not utilized.

### Comparative Example 2

A developer composition was prepared in substantially the same manner as in Preparation Example 1, except that 2.0 wt % of acetic acid was utilized instead of 2-hydroxy-2, 4, 6-cycloheptatriene-1-one.

### Evaluation: Contrast Performance

An organic metal-containing photoresist (PR) for EUV was spin-coated on an 8-inch wafer at 1,500 rpm for 30 seconds and heat-treated at 100° C. for 60 seconds, manufacturing a coated wafer.

After exposing the coated wafer at a dose of 10 mJ to 50 mJ in a rectangular pattern with a size of 1.2 cm×0.9 cm by utilizing a KrF scanner (PAS 5500/700D, ASML) and heat-treating it at 170° C. for 60 seconds, the developer compositions according to Examples 1 to 3 and Comparative Examples 1 and 2 were respectively applied thereto for developing and then, heat-treated at 150° C. for 60 seconds, completing a patterned wafer. The patterned wafer was measured with respect to a thickness of each exposure area to obtain a contrast curve, which was utilized to calculate contrast (γ) performance, and the results are shown in Table 1.

γ (contrast)=1/log(D₁₀₀/D₀)

D₁₀₀=exposure dose at which 100% of PR begins to remain

D₀=exposure dose at which PR is completely removed

TABLE 1

| | γ (contrast) |
|---|---|
| Example 1 | 8.7 |
| Example 2 | 8.8 |
| Example 3 | 10.3 |
| Comparative | 6.8 |
| Example 1 | |
| Comparative | 5.5 |
| Example 2 | |

Referring to Table 1, when the metal-containing photoresist developer composition according to Examples 1 to 3 is applied, superior contrast performance was exhibited compared to the embodiment in which the metal-containing photoresist developer composition according to Comparative Examples 1 and 2 is applied.

The use of “may” when describing embodiments of the present disclosure refers to “one or more embodiments of the present disclosure.”

As used herein, the term “substantially,” “about,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Also, any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this disclosure is intended to include all higher numerical limitations subsumed therein. Accordingly, Applicant reserves the right to amend this disclosure, including the claims, to expressly recite any sub-range subsumed within the ranges expressly recited herein.

The photoresist coating apparatus, the metal-containing resist or any other relevant metal-containing resist manufacture, control or management devices or components according to embodiments of the present disclosure described herein may be implemented utilizing any suitable hardware, firmware (e.g., an application-specific integrated circuit), software, or a combination of software, firmware, and hardware. For example, the various components of the apparatus or device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

Although the embodiments of the present disclosure have been described, it is understood that the present disclosure should not be limited to these embodiments, but one or more suitable changes and modifications can be made by one ordinary skilled in the art within the spirit and scope of the present disclosure as defined by the following claims and equivalents thereof.

### REFERENCE NUMERALS

100: substrate

110: feature layer

110P: feature pattern

130P: photoresist pattern

What is claimed is:

1. A metal-containing photoresist developer composition for a metal-containing photoresist, the composition comprising:
an organic solvent; and
a heptagonal ring compound substituted with at least one hydroxyl group (—OH),
wherein the heptagonal ring compound has at least two double bonds in the ring.

2. The metal-containing photoresist developer composition of claim 1, wherein
the heptagonal ring compound is substituted with one or two hydroxyl groups (—OH).

3. The metal-containing photoresist developer composition of claim 1, wherein
the heptagonal ring compound has three double bonds.

4. The metal-containing photoresist developer composition of claim 1, wherein
the heptagonal ring compound is represented by Chemical Formula 1: 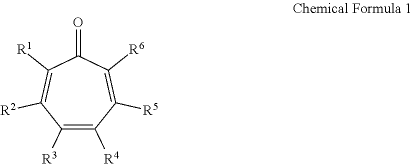
wherein, in Chemical Formula 1,
R¹ to R⁶ are each independently hydrogen, a halogen, a hydroxy group, an amino group, a substituted or unsubstituted C1 to C30 amine group, a substituted or unsubstituted C1 to C10 alkyl group, or a substituted or unsubstituted C6 to C20 aryl group, and
at least one of R¹ to R⁶ is a hydroxy group.

5. The metal-containing photoresist developer composition of claim 1, wherein
the heptagonal ring compound is selected from the formulas of Group 1: 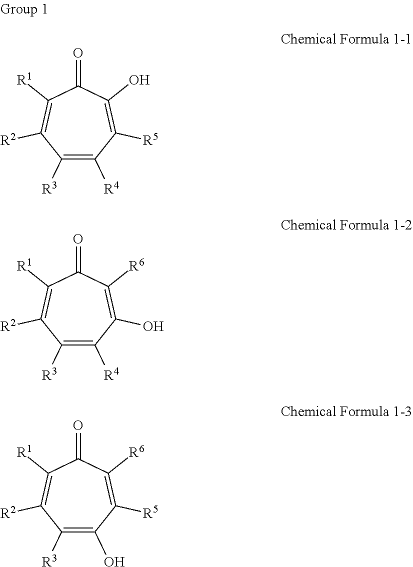
wherein, in Group 1,
R¹ to R⁶ are each independently hydrogen, a halogen, an amino group, a substituted or unsubstituted C1 to C30 amine group, a substituted or unsubstituted C1 to C10 alkyl group, or a substituted or unsubstituted C6 to C20 aryl group.

6. The metal-containing photoresist developer composition of claim 1, wherein
the heptagonal ring compound is 2-hydroxy-2,4,6-cycloheptatrien-1-one.

7. The metal-containing photoresist developer composition of claim 1, wherein
the composition comprises about 50 wt % to about 99.99 wt % of the organic solvent; and
about 0.01 wt % to about 50 wt % of the heptagonal ring compound.

8. The metal-containing photoresist developer composition of claim 1, wherein
the metal-containing photoresist comprises an alkyl tin oxo group and/or an alkyl tin carboxyl group.

9. The metal-containing photoresist developer composition of claim 1, wherein
the metal-containing photoresist comprises a metal compound represented by Chemical Formula 3: 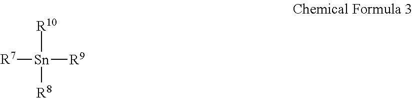
wherein, in Chemical Formula 3,
R⁷ is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C6 or C30 arylalkyl group, or —R^{a}—O—R^{b} (wherein R^{a} is a substituted or unsubstituted C1 to C20 alkylene group and R^{b} is a substituted or unsubstituted C1 to C20 alkyl group),
R⁸ to R¹⁰ are each independently —OR^{c} or —OC(═O)R^{d},
R^{c} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
R^{d} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof.

10. A method of forming patterns, the method comprising
coating a metal-containing photoresist composition on a substrate;
coating the metal-containing photoresist composition for removing edge beads from a metal-containing photoresist along an edge of the substrate;
drying and heating the coated resultant to form a metal-containing photoresist film on the substrate;
exposing the metal-containing photoresist film; and
developing the metal-containing photoresist film utilizing the metal-containing photoresist developer composition of claim 1.

11. A system of forming patterns, the system comprising
means for coating a metal-containing photoresist composition on a substrate;
means for coating the metal-containing photoresist composition for removing edge beads from a metal-containing photoresist along an edge of the substrate;
means for drying and heating the coated resultant to form a metal-containing photoresist film on the substrate;
means for exposing the metal-containing photoresist film; and
means for developing the metal-containing photoresist film utilizing the metal-containing photoresist developer composition of claim 1.
